(19) United States
(12) Patent Application Publication
(10) Pub. No.: US 2007/0105397 A1
(43) Pub. Date: May 10, 2007

(54) Method for removing hydrogen gas from a chamber

(76) Inventors: Jae-hwa Park, Yongin-si (KR); Woong-hee Sohn, Seoul (KR); Byung-hak Lee, Suwon-si (KR); Byung-hee Kim, Seoul (KR); Hee-seok Park, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/593,598

(22) Filed: Nov. 7, 2006

(30) Foreign Application Priority Data
Nov. 10, 2005 (KR) 10-2005-0107619

(51) Int. Cl. H01L 21/31

(52) U.S. Cl. 438/758

(57) ABSTRACT

Embodiments of the invention provide a method for removing hydrogen gas from a chamber and a method for performing a semiconductor device fabrication sub-process and removing hydrogen gas from a chamber. The method for removing hydrogen gas from a chamber comprises removing a substrate from a chamber, wherein residual hydrogen gas is disposed in the chamber, injecting oxygen gas or ozone gas into the chamber, producing plasma in the chamber, and removing OH radicals from the chamber.

### BACKGROUND

1. Field of the Invention

Embodiments of the invention relate to a method for removing hydrogen gas from a chamber. In particular, embodiments of the invention relate to a method for removing hydrogen gas from a chamber and a method for removing hydrogen gas from a chamber in which a semiconductor device fabrication sub-process was performed at least once.

This application claims priority to Korean Patent Application No. 10-2005-0107619, filed on Nov. 10, 2005, the subject matter of which is hereby incorporated by reference in its entirety.

2. Description of Related Art

Because of the current demand for semiconductor memory devices having high degrees of integration, the design rule for semiconductor devices is decreasing rapidly. In addition, as the amount of space between conductive wires in a semiconductor memory device is decreased, the resistance of the wires is increased. However, in order to increase the operational speed of a semiconductor memory device, the electrical resistance of the wires in the semiconductor memory device should be reduced. Thus, the wires formed in a semiconductor memory device should be formed having relatively low resistance.

A conductive pattern, and more specifically, a gate electrode of a semiconductor memory device and is formed in part from a pure metal layer formed from tungsten (W) or titanium (Ti) and is also formed in part from a conductive material such as polysilicon and metal silicide. When an etching process is performed to form the gate electrode, the side wall of the gate electrode and portions of the silicon substrate disposed on sides (i.e., both sides) of the gate electrode may be damaged by the etching process. Damage caused to the gate electrode and the silicon substrate by the etching process may be detrimental to properties of the transistor. Thus, a re-oxidation process should be performed after the etching process is performed in order to repair the damage caused to the gate electrode and the silicon substrate by the etching process.

However, since the metal layer of the gate electrode formed from a metal such as tungsten (W) reacts with oxygen more quickly than polysilicon reacts with oxygen, the exposed surface of the tungsten layer is abnormally oxidized during the re-oxidation process. Thus, it is difficult to selectively oxidize only the polysilicon of the gate electrode and the silicon substrate. Currently, damage suffered by the gate electrode is repaired through a selective oxidation process using plasma that is performed at a relatively low temperature.

When using hydrogen (H₂) gas in a selective oxidation process using plasma that is performed at a relatively low temperature, the oxidation rate varies greatly depending on the flow rate of the hydrogen gas. Thus, before a subsequent selective oxidation process is performed in a chamber after a preceding selective oxidation process has been performed in the chamber, hydrogen gas used in the preceding selective oxidation process must be completely removed from the chamber. However, when the interior of a chamber has a relatively low temperature and a relatively low pressure it is very difficult to completely remove the hydrogen gas from the chamber using a vacuum pump.

Thus, when a selective oxidation process is repeatedly performed in a chamber, the hydrogen gas used in a preceding selective oxidation process remains in the chamber for the subsequent selective oxidation process. So, when the selective oxidation process is repeatedly performed on a plurality of semiconductor substrates, the thicknesses of the respective oxide films formed on the semiconductor substrates on which the process was performed during relatively early repetitions of the process vary. Thus, it is difficult to perform selective oxidation processes having uniform results.

### SUMMARY OF THE INVENTION

Aspects of the invention provide a method for removing hydrogen gas from a chamber and a method for performing a semiconductor device fabrication sub-process and removing hydrogen gas from a chamber, wherein each method removes hydrogen gas from the chamber more effectively than a conventional method for removing hydrogen gas.

One aspect of the invention provides a method for removing gas from a chamber. The method comprises removing a substrate from a chamber, wherein residual hydrogen gas is disposed in the chamber; injecting oxygen gas or ozone gas into the chamber; producing plasma in the chamber; and removing OH radicals from the chamber.

Another aspect of the invention provides a selective oxidation and gas removal method comprising loading a semiconductor substrate comprising a metal gate pattern into a chamber, performing a selective oxidation process on the semiconductor substrate, wherein the selective oxidation process comprises injecting hydrogen gas and oxygen gas into the chamber, and removing the semiconductor substrate from the chamber. The method further comprises injecting additional oxygen gas or ozone gas into the chamber, producing plasma in the chamber, and removing OH radicals from the chamber.

Yet another aspect of the invention provides a selective oxidation and gas removal method comprising (a) loading a semiconductor substrate comprising a metal gate pattern into a chamber, wherein the semiconductor substrate is one of a lot of semiconductor substrates (b) performing a selective oxidation process on the semiconductor substrate, wherein the selective oxidation process comprises injecting hydrogen gas and oxygen gas into the chamber and (c) removing the semiconductor substrate from the chamber. The method further comprises (d) repeating (a) through (c) for each remaining semiconductor substrate in the lot of semiconductor substrates; (e) injecting additional oxygen gas or ozone gas into the chamber; (f) producing plasma in the chamber; and (g) removing OH radicals from the chamber.

### BRIEF DESCRIPTION OF THE DRAWINGS

Embodiments of the invention will be described herein with reference to the accompanying drawings, in which like reference symbols indicate like or similar elements. In the drawings:

FIG. 1 is a cross-sectional view illustrating a chamber in which a semiconductor device fabrication sub-process is performed in accordance with an embodiment of the invention;

FIG. 2 is a flowchart illustrating a substrate processing and gas removal method in accordance with an embodiment of the invention;

FIG. 3 is a graph showing the result of optical emission spectroscopy (OES) when producing plasma in a state in which hydrogen gas and oxygen gas are mixed together in accordance with a substrate processing and gas removal method in accordance with an embodiment of the invention;

FIG. 4A is a graph showing the respective thicknesses of oxide films formed on semiconductor substrates of a first lot after an oxidation process has been performed on each substrate of the first lot in accordance with a conventional technique; and,

FIG. 4B is a graph showing the respective thicknesses of oxide films formed on semiconductor substrates of a second lot after an oxidation process has been performed on each substrate of the second lot using a substrate processing and gas removal method in accordance with an embodiment of the invention.

### DESCRIPTION OF EMBODIMENTS

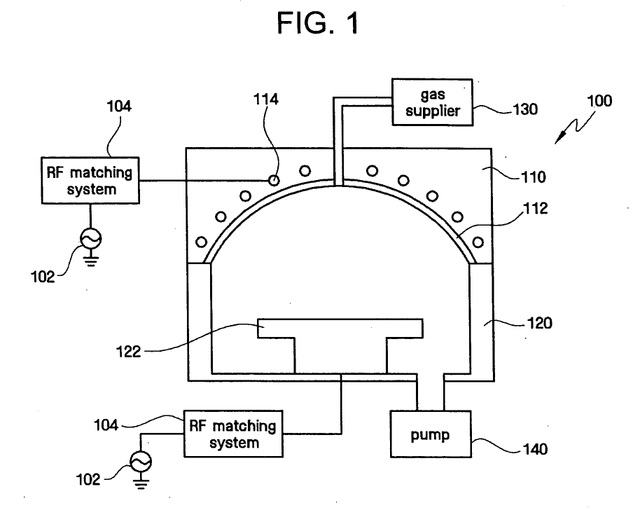

FIG. 1 is a cross-sectional view illustrating a chamber in which a semiconductor device fabrication sub-process is performed in accordance with an embodiment of the invention. As used herein, a “semiconductor device fabrication sub-process” is one of a plurality of processes performed in a semiconductor device fabrication process. A chamber 100 in which a semiconductor device fabrication sub-process is performed will now be described with reference to FIG. 1.

As shown in FIG. 1, the chamber 100 comprises an upper portion 110, a lower portion 120, a gas supplier 130, and a pump 140. The upper portion 110 comprises a dome-shaped cover 112 that covers the lower portion 120. The dome-shaped cover 112 is formed from ceramic material and is adapted to uniformly distribute plasma over the entire surface of a semiconductor substrate disposed in the chamber when plasma is produced in the chamber. In addition, an induction coil 114 is mounted around the cover 112, and an RF generator 102 and an RF matching system 104, which are inductively coupled in order to produce and maintain high-density plasma, are connected to the induction coil 114. Also, the gas supplier 130 is connected to the upper portion 110 to supply reactive gas into the upper portion 110.

In operation, the gas supplier 130 supplies reactive gas to the upper portion 110 of the chamber 100, and RF power is applied to the induction coil 114, and plasma is thereby created as the reactive gas in the chamber 100 is electrically discharged.

In addition, an electrostatic chuck 122 adapted to hold a semiconductor substrate using electrostatic force is mounted in the lower portion 120. The electrostatic chuck 122 is connected to an RF generator 102 (which is adapted to apply a bias voltage) and an RF matching system 104 so that the reactive gas in a plasma state may be moved toward the semiconductor substrate.

Additionally, the pump 140 is mounted to the lower portion 120 and is adapted to forcibly remove impurities and gas that has not reacted from the chamber 100. Thus, while a semiconductor device fabrication sub-process is being performed in the chamber, the pressure in the chamber 100 may be controlled in accordance with the operation of the pump 140.

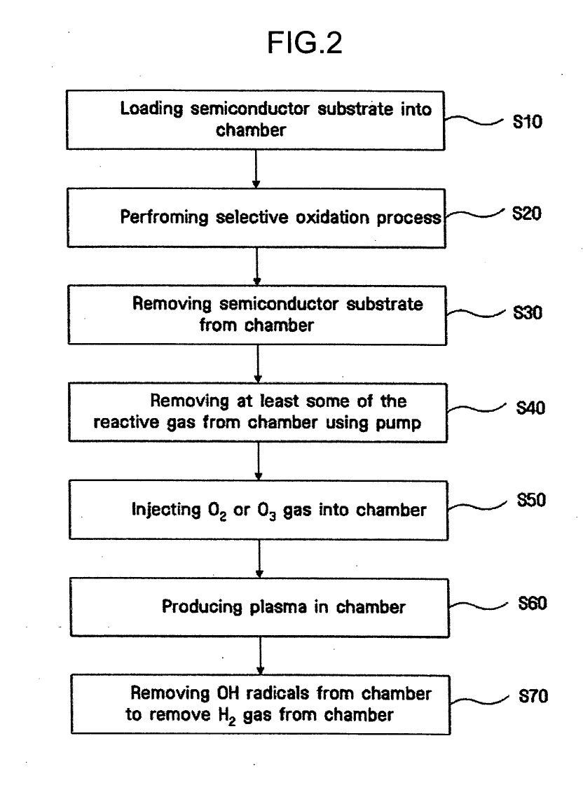

FIG. 2 is a flowchart illustrating a substrate processing and gas removal method in accordance with an embodiment of the invention. The substrate processing and gas removal method in accordance with an embodiment of the invention is described herein with reference to a selective oxidation process using plasma that is performed at a relatively low temperature. The substrate processing and gas removal method, in accordance with an embodiment of the invention, will now be described with reference FIGS. 1 and 2.

First, the interior of the chamber 100 is set to process conditions in which it is possible to perform a selective oxidation process, which uses plasma, at a relatively low temperature. That is, the interior of the chamber 100 is set to and maintained at a relatively low temperature of between about 25 and 600° C., inclusive, and a relatively low pressure of between about 10 and 200 Pa, inclusive.

After the atmosphere of the interior of the chamber 100 is set in accordance with the process conditions described above, a semiconductor substrate comprising a metal gate pattern is loaded into the chamber 100 (S10). The metal gate pattern of the semiconductor substrate may have a polysilicon film/metal layer structure or a polysilicon film/barrier metal film/metal layer structure. The metal layer may be formed from at least one substance selected from the group consisting of W, Ni, Co, TaN, Ru—Ta, TiN, Ni—Ti, Ti—Al—N, Zr, Hf, Ti, Ta, Mo, MoN, WN, Ta—Pt, Ta—Ti, and W—Ti. In addition, the barrier metal film, if present, may be formed from at least one substance selected from the group consisting of WN, TiN, TaN, and TaCN.

After the semiconductor substrate has been transferred into the chamber 100, the semiconductor substrate is stabilized for a predetermined amount of time in order to set the temperature of the semiconductor substrate to a temperature similar to the temperature of the electrostatic chuck 122. Then, hydrogen gas is supplied into the chamber 100 under a process pressure of between about 10 and 200 Pa, inclusive.

Thus, the semiconductor substrate is loaded into the chamber 100 and the atmosphere in the chamber 100 is maintained (or reestablished) in accordance with the process conditions, and then a selective oxidation process using plasma that is performed at a relatively low temperature is performed on the semiconductor substrate comprising the metal gate pattern (S20).

In more detail, the hydrogen gas is supplied into the chamber 100, wherein the semiconductor substrate is disposed in the chamber 100 and the interior of the chamber 100 is maintained at a relatively low temperature and a relatively low pressure. RF power is then applied to the chamber 100, and thereby, while the hydrogen gas is electrically discharged, hydrogen gas in a plasma state is produced (i.e., hydrogen radicals are produced).

Subsequently, oxygen gas is supplied into the chamber 100 in which the hydrogen radicals are disposed, thereby selectively oxidizing the semiconductor substrate comprising the metal gate pattern. That is, both sides of the polysilicon film of the metal gate pattern and the surface of the silicon substrate at both sides of the metal gate pattern are oxidized. When the selective oxidation process is performed as described above, the flow rate ratio of the hydrogen gas and the oxygen gas (i.e., H₂:O₂) may be between 2:1 and 20:1, inclusive, and the sum of the flow rate of the hydrogen gas and the oxygen gas may be between about 400 and 1000 sccm (standard cubic centimeters per minute), inclusive.

After the selective oxidation process performed on the semiconductor substrate has been completed, the semiconductor substrate is removed from the chamber 100 (i.e., unloaded to the outside of the chamber 100) (S30). Thereafter, at least some of the reactive gas is removed from the chamber 100 using the pump 140 (S40). However, since the interior of the chamber 100 is maintained at a relatively low temperature and at a relatively low pressure, some of the hydrogen gas may remain in the chamber 100.

In order to remove the residual hydrogen gas (i.e., the hydrogen gas remaining in the chamber 100) from the chamber 100, additional oxygen gas or ozone gas is injected into the chamber 100 from which the semiconductor substrate has been removed (S50). As the additional oxygen gas or the ozone gas is injected into the chamber 100, the inside of the chamber 100 is maintained at a relatively low temperature of between about 25 and 600° C., inclusive, and at a relatively low pressure of between about 10 and 200 Pa, inclusive. The flow rate ratio of the hydrogen gas and the oxygen gas in the chamber 100 (i.e., H₂/(H₂+O₂)) is between about 0.2 and 0.8, inclusive.

When the RF power is then applied to the chamber 100, hydrogen radicals and oxygen radicals are produced. Subsequently, the hydrogen radicals react with the oxygen radicals to produce OH radicals. The OH radicals thus produced may be removed from the chamber 100 (i.e., emitted to the outside) using the pump 140.

Thus, the oxygen gas or ozone gas is injected into the chamber in which the residual hydrogen gas is disposed thus producing plasma (S60). OH Radicals may be produced as described above, and the residual hydrogen gas may be removed from the chamber 100 in the form of OH radicals (S70).

In the substrate processing and gas removal method in accordance with an embodiment of the invention, after the selective oxidation process has been performed on a semiconductor substrate, the semiconductor substrate may be removed from the chamber 100 and oxygen gas or ozone gas may be injected into the chamber 100 to remove the residual hydrogen gas from the chamber 100. In an alternative embodiment, the process for removing the residual hydrogen gas from the chamber may be performed after the selective oxidation process has been performed on each semiconductor substrate of an entire lot of semiconductor substrates. That is, steps S10 through S40 of FIG. 2 may be sequentially performed on each semiconductor substrate of the lot, and steps S50 through S70 may be performed to remove the residual hydrogen gas from the chamber after steps S10 through S40 of FIG. 2 have been sequentially performed on each semiconductor substrate of the lot. Thus, the process for removing the residual hydrogen gas may be performed only periodically rather than after each time the selective oxidation process is performed on a semiconductor substrate.

The results of an assessment of a substrate processing and gas removal method in accordance with an embodiment of the invention will now be described.

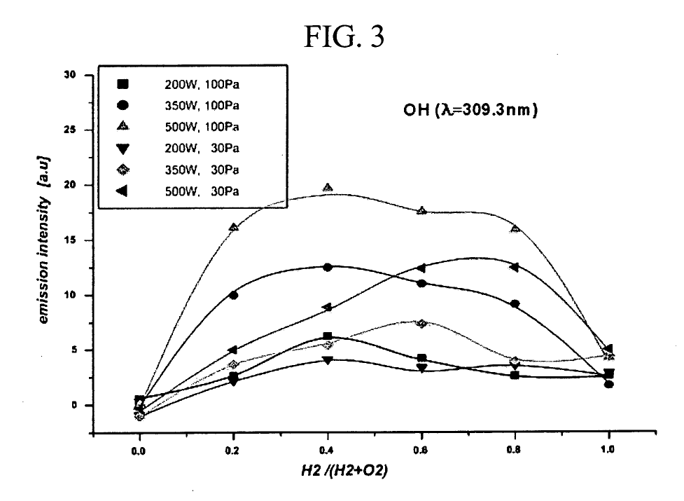

FIG. 3 is a graph showing the result of optical emission spectroscopy (OES) when producing plasma in a state in which the hydrogen gas and the oxygen gas are mixed together in accordance with a substrate processing and gas removal method in accordance with an embodiment of the invention. In particular, FIG. 3 is a graph showing the emission intensity of the OH radicals in accordance with the flow rate ratio of the hydrogen gas and the oxygen gas (i.e., H₂/(H₂+O₂)).

Referring to FIG. 3, the emission intensity of the OH radicals generally increases as the RF power (expressed in FIG. 3 in terms of W) increases. In addition, when the pressure is about 100 Pa, the emission intensity of the OH radical is generally relatively high when the flow rate ratio of the hydrogen gas and the oxygen gas (i.e., H₂/(H₂+O₂)) is between 0.2 and 0.8, inclusive. Further, when the pressure is about 30 Pa, the emission intensity of the OH radical may be relatively high when the flow rate ratio of the hydrogen gas and the oxygen gas (i.e., H₂/(H₂+O₂)) is between about 0.6 and 0.8, inclusive.

Therefore, at a relatively low pressure, the hydrogen gas may have a relatively high emission intensity with respect to the hydrogen radicals. Oxygen radicals produced using the oxygen gas or ozone gas react with the hydrogen radicals to thereby form OH radicals, and the residual hydrogen gas disposed in a chamber may be removed from the chamber in the form of OH radicals.

When performing a substrate processing and gas removal method in accordance with an embodiment of the invention, the results shown in FIG. 3 may be used to determine a level of pressure at which to maintain the interior of a chamber and an amount of RF power to apply to the chamber in order to achieve a desired flow rate ratio of the hydrogen gas and the oxygen gas used to produce the OH radicals so that the residual hydrogen gas may be effectively removed from the chamber.

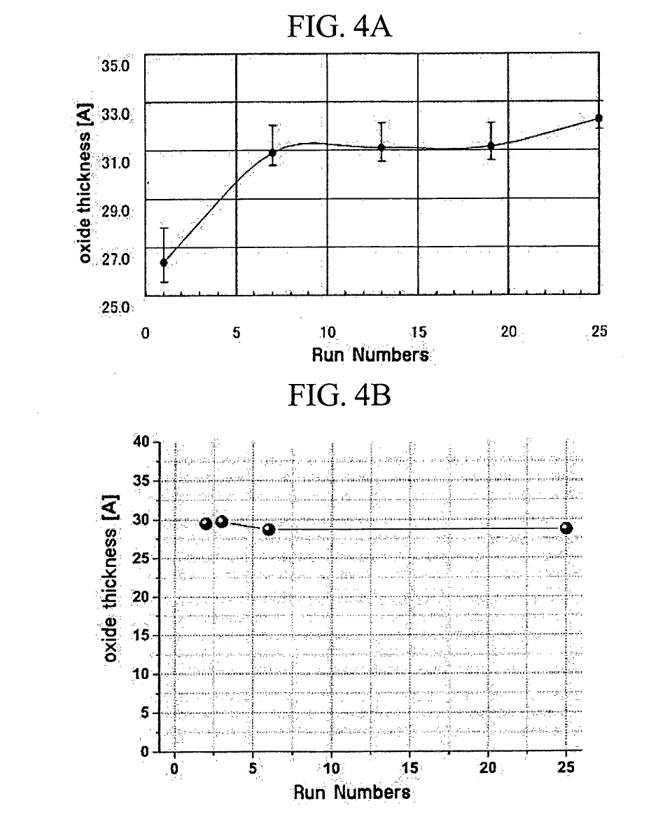

FIG. 4A is a graph showing the respective thicknesses of oxide films formed on semiconductor substrates of a first lot after an oxidation process has been performed on each substrate of the first lot in accordance with a conventional technique. The graph of FIG. 4A shows, for each repetition (i.e., run) of the conventional oxidization process, the thickness of the oxide film formed on the substrate on which the process was performed during that repetition, and thus shows the variation in the thicknesses of the oxide films formed on the substrates of the first lot. FIG. 4B is a graph showing the respective thicknesses of oxide films formed on semiconductor substrates of a second lot after an oxidation process has been performed on each substrate of the second lot using a substrate processing and gas removal method in accordance with an embodiment of the invention. The graph of FIG. 4B shows, for each repetition (i.e., run) of the substrate processing and gas removal method in accordance with an embodiment of the invention, the thickness of the oxide film formed on the substrate on which the method was performed during that repetition, and thus shows the variation in the thicknesses of the oxide films formed on the substrates of the second lot.

When the conventional oxidization process is repeatedly performed, a subsequent oxidization process performed after a preceding oxidization process is performed in the presence of residual hydrogen gas that remains after the preceding oxidization process has been performed. As shown in FIG. 4A, the residual hydrogen gas affects the respective thicknesses of the oxide films formed on semiconductor substrates on which oxidation was performed during relatively early runs of the oxidation process.

However, the substrate processing and gas removal method in accordance with an embodiment of the invention removes hydrogen gas from the chamber, so when an oxidation process in accordance with an embodiment of the invention is performed on each substrate of a lot, the thicknesses of the respective oxide films formed on the semiconductor substrates processed during relatively early runs are more uniform, as shown in FIG. 4B. These results confirm that the substrate processing and gas removal method in accordance with an embodiment of the invention effectively removed the residual hydrogen gas disposed in the chamber.

As described previously, a substrate processing and gas removal method in accordance with an embodiment of the invention removes hydrogen gas remaining in a chamber after a semiconductor device fabrication sub-process has been performed in the chamber more effectively than a conventional process. Thus, repeatedly using a substrate processing and gas removal method in accordance with an embodiment of the invention to perform selective oxidation processes on a plurality of substrates, each of which comprises a metal gate pattern, may reduce the variation in the thicknesses of the oxide layers respectively formed on the plurality of substrates since oxide layer thickness is effected by remaining hydrogen gas. Therefore, using a substrate processing and gas removal method in accordance with an embodiment of the invention to perform selective oxidation processes on a plurality of substrates may improve the uniformity of the results of the selective oxidation processes performed on the plurality of substrates.

Although embodiments of the invention have been described herein, various modifications, additions, and substitutions may be made therein by those skilled in the art without departing from the scope of the invention as defined by the accompanying claims.

What is claimed is:

1. A method for removing gas from a chamber comprising:
removing a substrate from a chamber, wherein residual hydrogen gas is disposed in the chamber;
injecting oxygen gas or ozone gas into the chamber;
producing plasma in the chamber; and,
removing OH radicals from the chamber.

2. The method of claim 1, further comprising maintaining an interior of the chamber at a temperature between about 25 and 600° C., inclusive.

3. The method of claim 2, further comprising maintaining the interior of the chamber at a pressure between about 10 and 200 Pa, inclusive.

4. The method of claim 1, wherein, when injecting the oxygen gas into the chamber, injecting the oxygen gas into the chamber is performed at a flow rate ratio of the hydrogen gas (H₂) and the oxygen gas (O₂), expressed as H₂/(H₂+O₂), of between 0.2 and 0.8, inclusive.

5. The method of claim 1, wherein producing plasma in the chamber comprises applying RF power at a level sufficient to cause hydrogen radicals to react with oxygen radicals.

6. A selective oxidation and gas removal method comprising:
loading a semiconductor substrate comprising a metal gate pattern into a chamber;
performing a selective oxidation process on the semiconductor substrate, wherein the selective oxidation process comprises injecting hydrogen gas and oxygen gas into the chamber;
removing the semiconductor substrate from the chamber;
injecting additional oxygen gas or ozone gas into the chamber;
producing plasma in the chamber; and,
removing OH radicals from the chamber.

7. The method of claim 6, wherein the metal gate pattern comprises a polysilicon film/metal layer structure or a polysilicon film/barrier metal film/metal layer structure.

8. The method of claim 6, further comprising maintaining an interior of the chamber at a temperature of between about 25 and 600° C., inclusive.

9. The method of claim 6, further comprising maintaining an interior of the chamber at a pressure of between about 10 and 200 Pa, inclusive.

10. The method of claim 6, wherein, when injecting the hydrogen gas and the oxygen gas into the chamber to perform the selective oxidation process on the semiconductor substrate, a flow rate ratio of the hydrogen gas (H₂) to the oxygen gas (O₂), expressed as H₂:O₂, is between 2:1 and 20:1, inclusive.

11. The method of claim 6, wherein, when injecting the additional oxygen gas into the chamber, injecting the additional oxygen gas into the chamber is performed at a flow rate ratio of the hydrogen gas (H₂) and the oxygen gas (O₂), expressed as H₂/(H₂+O₂), of between 0.2 and 0.8, inclusive.

12. The method of claim 6, wherein producing plasma in the chamber comprises applying RF power at a level sufficient to cause hydrogen radicals to react with oxygen radicals.

13. A selective oxidation and gas removal method comprising:
(a) loading a semiconductor substrate comprising a metal gate pattern into a chamber, wherein the semiconductor substrate is one of a lot of semiconductor substrates;
(b) performing a selective oxidation process on the semiconductor substrate, wherein the selective oxidation process comprises injecting hydrogen gas and oxygen gas into the chamber;
(c) removing the semiconductor substrate from the chamber;
(d) repeating (a) through (c) for each remaining semiconductor substrate in the lot of semiconductor substrates;
(e) injecting additional oxygen gas or ozone gas into the chamber;
(f) producing plasma in the chamber; and,
(g) removing OH radicals from the chamber.

14. The method of claim 13, wherein the metal gate pattern comprises a polysilicon film/metal layer structure or a polysilicon film/barrier metal film/metal layer structure.

15. The method of claim 13, further comprising maintaining an interior of the chamber at a temperature of between about 25 and 600° C., inclusive.

16. The method of claim 13, further comprising maintaining an interior of the chamber at a pressure of between about 10 and 200 Pa, inclusive.

17. The method of claim 13, wherein, when injecting the hydrogen gas and the oxygen gas into the chamber to perform the selective oxidation process on the semiconductor substrate, a flow rate ratio of the hydrogen gas (H₂) to the oxygen gas (O₂), expressed as H₂:O₂, is between 2:1 and 20:1, inclusive.

18. The method of claim 13, wherein, when injecting the additional oxygen gas into the chamber, injecting the additional oxygen gas into the chamber is performed at a flow rate ratio of the hydrogen gas (H₂) and the oxygen gas (O₂), expressed as H₂/(H₂+O₂), of between 0.2 and 0.8, inclusive.

19. The method of claim 13, wherein producing plasma in the chamber comprises applying RF power at a level sufficient to cause hydrogen radicals to react with oxygen radicals.

20. The method of claim 19, wherein the RF power level ranges between about 100 and 700 kW.
